(19) United States
(12) Patent Application Publication
(10) Pub. No.: US 2009/0259416 A1
(43) Pub. Date: Oct. 15, 2009

(54) DEVICE FOR INSPECTING AN ELECTRIAL LINE'S PROTECTION ELEMENT AND FOR VERIFYING SAID ELECTRICAL LINE

(76) Inventor: Jesus Angel Oroz Garcia, Carrion de los Condes (ES)

Correspondence Address: JOHN D. TITUS;THE CAVANAGH LAW FIRM, 1850 N. CENTRAL AVENUE, SUITE 2400, PHOENIX, AZ, 85004, US

(21) Appl. No.: 12/303,038

(22) PCT Filed: Mar. 30, 2007
(86) PCT No.: PCT/EP07/02874

§ 371 Date: Dec. 1, 2008

(30) Foreign Application Priority Data
Jun. 2, 2006 (ES) P200601495

(51) Int. Cl. G01R 31/02; G06F 19/00; G08B 21/00

(52) U.S. Cl. 702/58; 324/537; 340/635

(57) ABSTRACT

Device for inspecting an electrical line's protection element and for verifying said electrical line disposed, in use, part in series and part in parallel with the corresponding protection element and comprising: processing means that control and functionally interconnect the other components of the device and that receive tension directly from a point of the line upstream of said protection element; means for measuring tension that include first and second measuring assemblies interposed between said processing means and the line; switching means situated on a bridge that interlinks the branches of the circuit on which said first and second measuring assemblies are located; and alerting means that inform of the status of said protection element and of the line.

### OBJECT OF THE INVENTION

The present invention relates to a device for inspecting an electrical line's protection element and for verifying said electrical line. The invention's device can be used on electrical line networks with one or more protection elements for each of the lines always on condition that their supply voltages are referenced in relation to each other.

More specifically, the present invention relates to an electrical/electronic device for inspecting the status of the protection element of an electrical line (of supply, signal or any other type) as well as to measure the current demanded by the associated load, with a view to gathering data on a potential anomalous state.

### BACKGROUND OF THE INVENTION

Electronic and electrical circuits are usually protected by elements that provide great safety in the event of short circuits and power surges, preventing the degradation of the devices and electrical lines to which they are connected.

However, at present there is no universal protection for any unforeseeable event that may occur on the line: rapid transients, sporadic power surges, etc. meaning that it is possible in some cases for a protection element to protect a line excessively or on the contrary, not to protect it.

Additionally, some of these protection elements are destructive protection elements, such as melting plates, which generate current transients similar to those of an inductance and which can degrade the associated load at the moment they activate.

In all events, it is advisable to verify the reasons for the protection element's activation prior to rearming it, since depending on its nature, one action or another will be required (such as rearming the protection element, repairing the line, replacing the load due to its deterioration, etc.)

The verification devices in existence for this purpose present some disadvantages, including especially that they function on the basis of current intensity measurements (which are harder to handle than voltage measurements) and that their application for joint verification of a number of lines requires, as a minimum, a highly complex adaptation.

### SUMMARY OF THE INVENTION

The present invention solves the problems mentioned above through a device for inspecting the status of an electrical line's protection element and for measuring the current demanded by the associated load with a view to gathering data on a potential anomalous state. The present application is also directed to a corresponding method.

The device of the present invention for inspecting an electrical line's protection element and for verifying said electrical line is disposed, in use, permanently or in a removable manner, part in series and part in parallel with the corresponding protection element and comprises: processing means that control and functionally interconnect the other components of the device and that receive tension directly from a first point of the line upstream of said protection element; means for measuring tension that include a first measuring assembly (interposed between said processing means and a second point of the line upstream of said protection element) and a second measuring assembly (interposed between said processing means and a point of the line downstream of said protection element); switching means situated on a bridge that links the branches of the circuit on which the first and second line measuring assemblies are located; and alerting means that inform of the status of said protection element and the status of the line.

Obviously, these processing means can be digital (programmable logic, microprocessors, etc.) or analogue.

Optionally, the device of the present invention is equipped with tension stabilising means, disposed on the branch of the circuit that delivers tension to said processing means directly from a point of the line upstream of said protection element.

In the event that the line has its own switching means upstream and/or downstream of said protection device, the device of the present invention will be equipped with additional switching means, disposed in parallel with the line's own switching means.

The alerting means can be of any type, depending on the action to be taken and specific application. By way of example, these alerting means could emit luminous signals (LEDs, lamps, etc.), acoustic signals (varying sound frequencies, melodies, etc.), or communicate data (bluetooth, ethernet, etc.) or a combination thereof.

Depending on the values obtained by said tension measuring means and the values detected by said processing means, said processing means will identify various states of the line:
Inactive line status: In this state, the values are zero and no electrical current reaches the line. This state occurs when the line is disconnected from the supply by an element external to the device of the present invention (for example by a relay or switch) or presents a breakdown that interrupts the line upstream of the device of the present invention.
Active line status: This status occurs when the value of the positive terminal of said protection element is similar to the value of the supply. This status includes three alternative modes: that the difference in voltage is low (normal functioning status), that it has an average value (functioning mode at the protection element's limit) or value similar to the value of the supply or high (anomalous functioning mode). In the first mode, the electrical line does not present any breakdown and its functioning is correct electrically speaking. In the second mode, said protection element is functioning in a forced situation due to a demand of power close to that of its own activation. In the third mode, the protection element is simply active and no electrical current flows through the line.
Line verification status: This status occurs when the protection element is active, with a view to verifying the causes for which this status has been reached, or when the line is electrically deactivated and the intention is to verify the value of the load. Said switching means of the device of the present invention are closed with a view to being able to direct current to the load in a controlled manner.

In the event of the device of the present invention being shared by several lines, in other words, in electrical networks, the currents can be diverted from certain branches to others depending on the status of the various switching elements, the status of the protection elements and the values of the loads, meaning that the algorithm defined herein for a single line must be generalised through resolution of the Junction and Loop Equations (Kirchoff rules). It is necessary to scan the diverse activation conditions of the switches that join the lines, thus obtaining a set of equations that determines the value of the loads and the state of each line's protection elements.

### BRIEF DESCRIPTION OF THE DRAWINGS

FIG. 1 shows a block diagram of the device of the present invention.

FIG. 2 shows a sketch of a first embodiment of the device of the present invention.

FIG. 3 shows a sketch of a second embodiment of the device of the present invention.

FIG. 4 shows a sketch of a third embodiment of the device of the present invention.

### DESCRIPTION OF THE EMBODIMENTS OF THE INVENTION

Hereinafter, Vₐ will designate the value of the electrical line's supply voltage, and V_{b} and V_{c} will designate respectively the voltage values of terminals B and C of the protection element. At the same time, V_{f} will designate a voltage value greater than zero and lower than Vₐ for which the protection element is close to its activation.

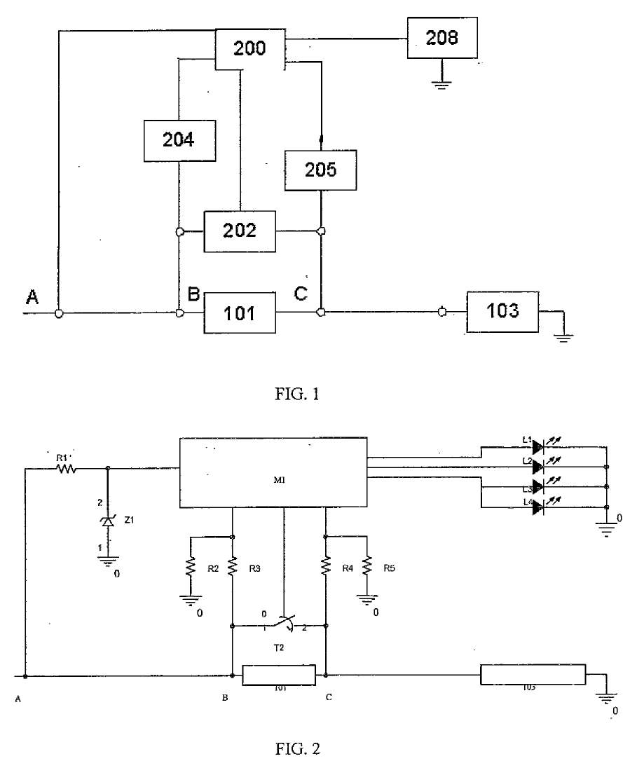

FIG. 1 shows a block diagram that illustrates the basis of a device for inspecting the protection element of an electrical line and for verifying the electrical line, according to the present invention, situated next to various elements external to the invention: the protection element itself, designated as 101, and the load of the line, designated as 103. The diagram shows the point of supply A and the terminals B and C of the protection element.

Said device for inspecting an electrical line's protection element and for verifying said electrical line, according to the present invention, comprises: processing means 200 that control and functionally interconnect the other components of the device; means for measuring tension that include a first measuring assembly 204 (interposed between said processing means and a point of the line upstream of said protection element 101) and a second measuring assembly 205 (interposed between said processing means and a point of the line downstream of said protection element 101); switching means 202 situated on a bridge that links the branches of the circuit on which the first and second line measuring assemblies 204 and 205 are located, connecting between them said circuit branches in a position between said first and second line measuring assemblies 204 and 205; and alerting means 208 that inform of the status of said protection element 101 and the status of the line (in this example, the status of said load 103).

FIG. 2 shows a first basic embodiment of the device according to the present invention.

In this embodiment, said device includes means for stabilising tension implemented with a zener diode Z₁ and a resistance R₁, tension measuring means that comprise a first tension divider formed by two resistive elements R₂ and R₃ and a second tension divider formed by two resistive elements R₄ and R₅, processing means that comprise a microprocessor M₁, alerting means that comprise LEDs L₁, L₂, L₃, L₄, and switching means that comprise a switch T₂ formed by a MOSFET transistor.

The functioning of said device is as follows:

Said microprocessor M₁ obtains tension values from said tension dividers R₂, R₃ and R₄, R₅ (which in this embodiment have a value which is 10 times higher than that of the line's maximum load on terminals B and C of the protection element 101). The absolute value of the measurements obtained in each one of these tension dividers R₂, R₃ and R₄, R₅ and the difference between them defines various states and actions:
If V_{b}=V_{c} and V_{b}=Vₐ the electrical line is functioning correctly in electrical terms. In this state it is not necessary to check the load 103 since there is no possibility of short circuit or power surges, unless expressly required. Said microprocessor M₁ would light up said LED L₁, corresponding to the correct functioning mode.
If V_{b}−V_{c}=V_{f} a new state is established wherein said protection element 101 is acting in a borderline state close to its activation. This state is due to a malfunctioning of said load 103, such as earthing, or a bad choice of protection element. Said microprocessor M₁ would light up said LED L₂, corresponding to a correct functioning.
If V_{b}−V_{c}≈Vₐ said protection element 101 is activated. This status may be due to a breakdown of the electrical line or of the load it supplies. The procedure is to verify the value of the current demand on the line to determine the causes of said protective element 101's activation. For this purpose, said microprocessor M₁ activates said controlled current switch T₂ during a short time interval with a view to being able to measure the demanded current on said tension divider R₄, R₅. It is necessary to be aware that the voltage of terminal C is that of the tension divider between the MOSFET transistor itself of said switch T₂ (which acts as a low Ohmic value resistance) and that of said load 103 (which has a negligible value against the tension divider R₄, R₅). For loads with a high capacitive or inductive value a train of pulses or other test signals is generated such as ramps, senoids, etc. Once the value of the current demand is calculated, the value of the intensity it requires is calculated. By comparing the computed value with the own values of said protection element 101, it is possible to determine whether or not there is a breakdown on the line. Said microprocessor M₁ would light up said LED L₃, corresponding to the situation of activated protection element without line breakdown, or said LED L₄, corresponding to line breakdown, respectively.

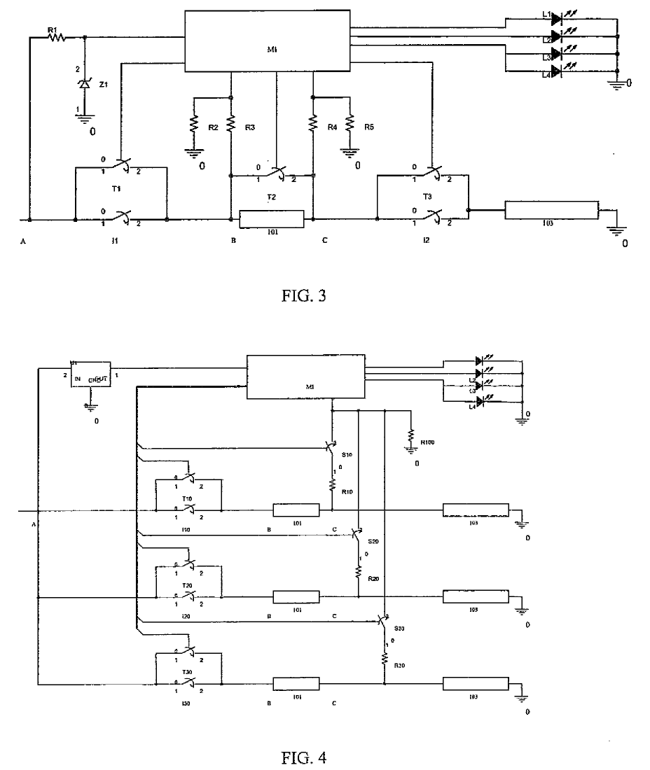

FIG. 3 shows a second more complete embodiment of the device according to the present invention.

In this embodiment, said device includes tension stabilising means realized with a zener diode Z₁ and a resistance R₁, tension measuring means that comprise a first tension divider formed by two resistive elements R₂ and R₃ and a second tension divider formed by two resistive elements R₄ and R₅, processing means that comprise a microprocessor M₁, alerting means that comprise LEDs L₁, L₂, L₃, L₄, and switching means that comprise a switch T₂ formed by a MOSFET transistor.

In this embodiment, said device also includes additional switching means, given that the line is equipped with its own switching means. Specifically, said device comprises a switch T₁ in parallel with a switch I₁ of the line, and a switch T₃ in parallel with a switch I₃ of the line (with all switches, in this embodiment, formed by MOSFET transistors).

The functioning of said device is similar to the functioning of the device of FIG. 2.

Said microprocessor M₁ obtains tension values from said tension dividers R₂, R₃ and R₄, R₅ (which in this embodiment have a value which is 10 times higher than that of the line's maximum load on terminals B and C of the protection element 101). The absolute value of the measurements obtained from each one of the tension dividers R₂, R₃ and R₄, R₅ and the difference between them define various states and actions:
If V_{b}=V_{c} and V_{b}=0 the electrical line is disconnected from the supply (switch I₁) and/or the load 103 (switch I₂) independently of the protection element's status. With a view to identifying the real situation of said protection element 101, said switch T₁ is activated during a short period of time and through said tension dividers R₂, R₃ and R₄, R₅ the voltage values are measured on the terminals of said protection element 101. If the difference in voltage between them is close to 0, said protection element 101 is deactivated, meaning that there is no breakdown on the line. Said microprocessor M₁ would light up said LED L_{I}, corresponding to correct functioning. In the opposite case (or by express requirement of line verification) the procedure is to measure the electrical current demand of a particular line by verification of the line's status.

Verification of the line's status: Said microprocessor M₁, activates said switches T₁, T₂, T₃ during a short time interval with a view to being able to measure on said tension divider R₄, R₅ the current demanded by said load 103. It is necessary to take into consideration that the voltage in terminal C is that of the tension divider between the MOSFET transistor itself of said switch T₂ (which acts as a low Ohmic value resistance) and that of said load 103 (which has a negligible value against the tension divider R₄, R₅). For loads with a high capacitive or inductive value a train of pulses or other test signals is generated such as ramps, senoids, etc. Once the value of the current demand is calculated, the value of the intensity it requires is calculated. By comparing the computed value with the own values of said protection element 101, it is possible to determine whether or not there is a breakdown on the line. Said microprocessor M₁ would light up said LED L₃, corresponding to the situation of activated protection element without line breakdown, or said LED L₄, corresponding to line breakdown, respectively.
If V_{b}=V_{c} and V_{b}≈Vₐ the electrical line is functioning correctly in an electrical context. In this state it is not necessary to check the load since there is no possibility of a short circuit or power surges, except through express requirement. Said microprocessor M₁ would light up said LED L₁, corresponding to correct functioning.
If V_{b}−V_{c}≈V_{f} said protection element 101 is acting in a borderline state close to its activation. This state is due to a malfunctioning of the load, earthing or a bad choice of protection element. Said microprocessor M₁ would light up said LED L₂, corresponding to correct functioning.
If V_{b}−V_{c}≈Vₐ said protection element 101 is activated or said switch I₂ of the line is open or both situations apply. To determine which case is correct, said switch T₂ is activated for a short time interval. If the values in said tension dividers R₂, R₃ and R₄, R₅ corresponding to the terminals of said protection element 101 continue unaltered, said protection element 101 is not active meaning that the line presents no malfunction. Said microprocessor M₁ would light up said LED L₁, corresponding to correct functioning.

If the values in said tension dividers R₂, R₃ and R₄, R₅ corresponding to the terminals of said protection element 101 have changed, said protection element 101 is active meaning that the status of the line must be verified as explained above (independently of the status of said switch I₂ of the line).
If V_{b}=V_{c} and V_{b}=0 the electrical line is disconnected from the supply Vₐ. In this state it is possible to check said protection element 101 through said switches T₁, T₂, T₃ by verifying the status of the line as explained above.

FIG. 4 shows a third embodiment of the device according to the present invention, for a network of lines (in this embodiment three lines) on which there is a protection element 101 and a load 103 for each one.

To identify each state, a combination of activating the transistors is made to obtain through the Kirchoff equations a set of equations and thus resolve the impedance values of the protection element of each line and the value of the load.

In this embodiment, said device comprises: tension stabilising means realized with a three terminal tension regulator U₁; tension measuring means that include a series combination R₁₀, S₁₀ for the first line, a series combination R₂₀, S₂₀ for the second line and a series combination R₃₀, S₃₀ for the third line, and a resistive element R₁₀₀ common to all lines; processing means that comprise a microprocessor M₁; alerting means that comprise LEDs L₁, L₂, L₃, L₄; and switching means T₁₀, T₂₀, T₃₀ formed by various MOSFET type transistors, situated in parallel, with respective switches I₁₀, I₂₀, I₃₀ of the line itself.

Verification of the activation status of each protection element 101 is achieved by individualized measurement of the tension in terminal C of said protection element 101 for each circuit. This measurement is taken before and after closing each switch T₁₀, T₂₀, T₃₀ on a first tension divider formed by R₁₀, R₁₀₀, a second tension divider formed by R₂₀, R₁₀₀ and a third tension divider formed by R₃₀, R₁₀₀, respectively, when said switch S₁₀, S₂₀, S₃₀ is activated.

This verification is complemented with the resolution of the set of equations of the loops generated when one or more switches S₁₀, S₂₀, S₃₀ are closed; measuring the tension present at the common point R₁₀₀, following the sequential closing of said switches T₁₀, T₂₀, T₃₀ of the circuits involved. A resolution of the equations set carried out by said microprocessor M₁, makes it possible to obtain the impedances of the combination of each one of the lines and of said loads 103 and consequently, to establish problems present on the lines or current demands in comparison with correct functioning values.

Naturally, maintaining the principle of the invention, the embodiments and constructive details can vary extensively in relation to what is described and illustrated herein without by doing so leaving the scope of the present invention.

For merely illustrative purposes, it is appropriate to clarify that the switching means of the device according to the invention can include transistors of MOSFET type, bipolar and commutation in general realized in semiconductor support, current sources governable by tension, relays or a combination thereof; and that the embodiment shown in FIG. 4 can be generalised to a network with any number of lines in which there is a protection element and a load for each one of them.

Finally, those skilled in the art will understand that the device according to the invention can be manufactured as an integrated circuit.

1. Device for inspecting a protection element (101) of an electrical line and for verifying said electrical line, comprising:
processing means (200; M₁);
means for measuring tension including
a first measuring assembly (204; R₂, R₃) interposed between said processing means (200; M₁) and a second point of the line (B) upstream of said protection element (101) and
a second measuring assembly (205; R₄, R₅; S₁₀, R₁₀, S₂₀, R₂₀, S₃₀, R₃₀, R₁₀₀) interposed between said processing means (200; M₁) and a point of the line (C) downstream of said element (101);
switching means (202; T₂) situated on a bridge interlinking the branches of the circuit on which said first and second line measuring assemblies (204, 205; R₂, R₃, R₄, R₅; S₁₀, R₁₀, S₂₀, R₂₀, S₃₀, R₃₀, R₁₀₀) are connected to the electrical line;
alerting means (208; L₁, L₂, L₃, L₄); and
switching means (T₁, T₃; T₁₀, T₂₀, T₃₀), disposed in parallel with switching means (I₁, I₂, I₁₀. I₂₀. I₃₀) of said line.

2. Device according to claim 1, further comprising means (R₁, Z₁; U₁) for stabilising tension, disposed on the branch of the circuit that delivers tension to said processing means (M₁).

3. Device according claim 1, wherein said device is applied on a group of electrical lines.

4. Device according to claim 1, wherein said alerting means (208) includes devices that emit luminous, acoustic, or data communication signals or a combination thereof.

5. Device according to claim 1, wherein said device is installed in either a permanent or removable manner.

6. Device according to claim 1, wherein said processing means (200) are analog.

7. Device according to claim 1, wherein said processing means (200) are digital.

8. Device according to claim 7, wherein said digital processing means (200) include programmable logic and/or at least one microprocessor.

9. Device according to claim 1, wherein said switching means (202; T₂; T₁, T₃; T₁₀, T₂₀, T₃₀, S₁₀, S₂₀, S₃₀) comprises
at least one commutation transistor implemented on a semiconductor support,
at least one source of current by tension, and/or
at least one relay.

10. Device according to claim 9, wherein said commutation transistor is of the MOSFET type, bipolar type or a combination of the two.

11. Device according to claim 1, wherein said device is manufactured as an integrated circuit.

12. Method of inspecting a protection element (101) of an electrical line and for verifying said electrical line, comprising:
measuring the value Vₐ of voltage at a first point of the line (A) upstream of said protection element (101),
measuring the value V_{b} of voltage at a second point of the line (B) upstream of said protection element (101),
measuring the value V_{c} of voltage at a point (C) downstream of said protection element (101),
providing processing means (200; M₁) for receiving said measured values for Vₐ V_{b} and V_{c} and determining a value V_{f} of a voltage corresponding to a value greater than zero and lower than said value of voltage for which said element (101) is close to its activation, with these states being:
state of disconnection from the supply and/or electrical load, determined by the voltage values V_{b}=V_{c}=0;
state of correct functioning of the line, determined by the voltage values V_{b}=V_{c}≈Vₐ;
state of borderline functioning of said protection element (101),
determined by the voltage values V_{b}−V_{c}=V_{f};
state of activation of said protection element (101), determined by the voltage values V_{b}−V_{c}=Vₐ;
state of deactivated line, deactivated line, determined by the voltage values V_{b}≈V_{c}=0; and
emitting a signal indicative of each state.

13. The method according to claim 12, wherein said processing means (200; M₁) generates pulses, trains. of ramp type test signals, solenoid type test signals or a combination thereof.
